(19) United States
(12) Patent Application Publication
(10) Pub. No.: US 2025/0014915 A1
(43) Pub. Date: Jan. 9, 2025

(54) SUBSTRATE PROCESSING SYSTEM AND SUBSTRATE PROCESSING METHOD USING THE SAME

(71) Applicant: Samsung Electronics Co., Ltd., Suwon-si (KR)

(72) Inventors: SANGJINE PARK, Suwon-si (KR); Ji Hwan PARK, Suwon-si (KR); KUNTACK LEE, Suwon-si (KR)

(21) Appl. No.: 18/390,182

(22) Filed: Dec. 20, 2023

(30) Foreign Application Priority Data
Jul. 5, 2023 (KR) 10-2023-0087156

(51) Int. Cl. H01L 21/67; G03F 7/16; H01L 21/66

(52) U.S. Cl. CPC H01L 21/67051; G03F 7/168; H01L 21/67034; H01L 21/67248; H01L 22/12

(57) ABSTRACT

Disclosed are substrate processing systems and substrate processing methods. The substrate processing method comprises performing an exposure process on a substrate, removing moisture on the substrate after the exposure process, performing a wetting process on the substrate from which the moisture is removed, and performing a drying process on the substrate after the wetting process. The step of removing the moisture on the substrate includes measuring a weight of the substrate and heating the substrate whose weight is measured. The step of performing the drying process on the substrate includes placing the substrate into a dry chamber and supplying the dry chamber with a supercritical fluid to dry a fluid on the substrate.

### CROSS-REFERENCE TO RELATED APPLICATION

This U.S. nonprovisional application claims priority under 35 U.S.C § 119 to Korean Patent Application No. 10-2023-0087156 filed on Jul. 5, 2023 in the Korean Intellectual Property Office, the disclosure of which is hereby incorporated by reference in its entirety.

### BACKGROUND

The present inventive concepts relate to a substrate processing system and a substrate processing method using the same, and more particularly, to a substrate processing system capable of removing moisture on a substrate before a supercritical fluid is used to process the substrate and a substrate processing method using the same.

A semiconductor device may be fabricated through various processes. For example, the semiconductor device may be manufactured through a photolithography process, an etching process, a deposition process, and a plating process. During a photolithography process for fabricating a semiconductor device, a wetting process may be performed to coat liquid, such as a developer, on a wafer. In addition, a drying process may be executed/performed to remove the liquid coated on the wafer. Various methods may be used to coat the liquid on the wafer or to remove the liquid from the wafer.

### SUMMARY

Some embodiments of the present inventive concepts provide a substrate processing system capable of removing moisture on a substrate to prevent contamination and a substrate processing method using the same.

Some embodiments of the present inventive concepts provide a substrate processing system capable of removing moisture on a substrate while reducing damage to the substrate and a substrate processing method using the same.

Some embodiments of the present inventive concepts provide a substrate processing system capable of increasing yield and a substrate processing method using the same.

The objects of the present inventive concepts are not limited to the mentioned above, and other objects which have not been mentioned above will be clearly understood to those skilled in the art from the following description.

According to some embodiments of the present inventive concepts, a substrate processing method may comprise: performing an exposure process on a substrate; removing moisture on the substrate after the exposure process; performing a wetting process on the substrate from which the moisture is removed; and performing a drying process on the substrate after the wetting process. The step of removing the moisture on the substrate may include: measuring a weight of the substrate; and heating the substrate whose weight is measured. The step of performing the drying process on the substrate may include: placing the substrate into a dry chamber; and supplying the dry chamber with a supercritical fluid to dry a fluid on the substrate.

According to some embodiments of the present inventive concepts, a substrate processing method may comprise: performing a photolithography process on a substrate; after the photolithography process, transferring the substrate to a substrate drying system; and performing a cleaning process on the substrate using the substrate drying system. The performing of the cleaning process may include: removing moisture on the substrate after the substrate is transferred to the substrate drying system; performing a wetting process on the substrate after the moisture is removed; and performing a drying process on the substrate after the wetting process is completed. The step of removing the moisture on the substrate may include heating the substrate. The step of performing the drying process on the substrate may include supplying the substrate with a supercritical fluid to dry a fluid on the substrate.

According to some embodiments of the present inventive concepts, a substrate processing system may comprise a substrate drying system. The substrate drying system may include: a first substrate weight measuring apparatus configured to measure a weight of a substrate; a heating apparatus configured to heat the substrate removed from the first substrate weight measuring apparatus; a wetting apparatus configured to spray a fluid on the substrate removed from the heating apparatus; and a drying apparatus configured to dry the substrate removed from the wetting apparatus. The first substrate weight measuring apparatus may include: a measurement chamber that provides a measurement space; a measurement stage in the measurement chamber; and a weight detection sensor configured to detect the weight of the substrate disposed on the measurement stage. The drying apparatus may include: a dry chamber; and a dry fluid supply configured to supply the dry chamber with a supercritical fluid.

Details of other example embodiments are included in the following description and enclosed drawings.

### BRIEF DESCRIPTION OF DRAWINGS

FIG. 1 illustrates a simplified schematic diagram showing a substrate processing system according to some embodiments of the present inventive concepts.

FIG. 2 illustrates a cross-sectional view showing a wetting apparatus according to some embodiments of the present inventive concepts.

FIG. 3 illustrates a cross-sectional view showing a substrate weight measuring apparatus according to some embodiments of the present inventive concepts.

FIG. 4 illustrates a plan view showing a substrate weight measuring apparatus according to some embodiments of the present inventive concepts.

FIG. 5 illustrates a cross-sectional view showing a drying apparatus according to some embodiments of the present inventive concepts.

FIG. 6 illustrates a simplified schematic diagram showing a dry fluid supply according to some embodiments of the present inventive concepts.

FIG. 7 illustrates a flow chart showing a substrate processing method according to some embodiments of the present inventive concepts.

FIGS. 8 to 16 illustrate diagrams showing a substrate processing method according to the flow chart of FIG. 7.

### DETAILED DESCRIPTION OF EMBODIMENTS

The following will now describe some embodiments of the present inventive concepts with reference to the accompanying drawings. Like reference numerals may indicate like components throughout the description.

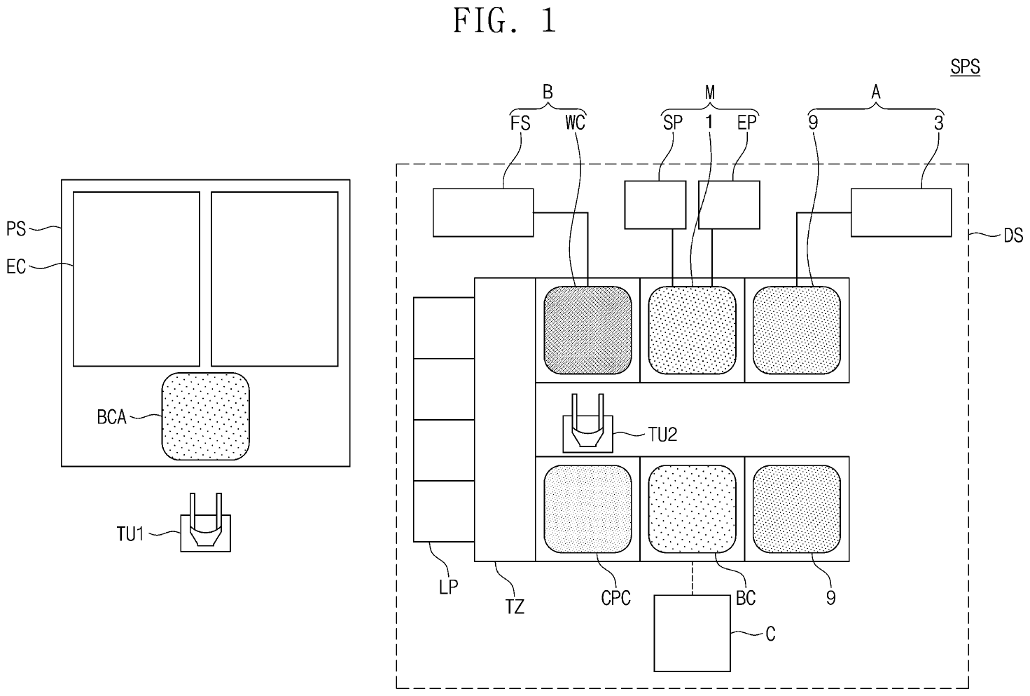

FIG. 1 illustrates a simplified schematic diagram showing a substrate processing system according to some embodiments of the present inventive concepts.

Referring to FIG. 1, a substrate processing system SPS may be provided. The substrate processing system SPS may be an apparatus in which a substrate is processed in a semiconductor fabrication process. For example, the substrate processing system SPS may be an apparatus allowing a substrate to undergo an exposure process, a wetting process, and a drying process. For example, the substrate processing system SPS may perform an exposure process, a wetting process and/or a drying process on the substrate. The substrate processing system SPS may be configured to radiate light to a substrate, to provide fluid to wet the substrate, and/or to remove fluid from a substrate to dry and clean the substrate. In this description, the term “substrate” may indicate a semiconductor wafer. The wafer may include or may be a silicon (Si) wafer, but the present inventive concepts are not limited thereto. The substrate processing system SPS may include or be formed of a photolithography processing system PS and a substrate drying system DS.

As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”.

The photolithography processing system PS may perform a photolithography process on a substrate. The photolithography processing system PS may include an exposure apparatus EC and a first heating apparatus BCA. The exposure apparatus EC may perform an exposure process on a substrate. For example, the exposure apparatus EC may radiate an extreme ultraviolet (EUV) radiation onto a substrate. The first heating apparatus BCA may heat a substrate. For example, the first heating apparatus BCA may perform a bake process on a substrate. The first heating apparatus BCA will be further discussed in detail below.

The substrate drying system DS may be disposed spaced apart from the photolithography processing system PS. A substrate that has passed (e.g., been processed) through the photolithography processing system PS may be transferred to the substrate drying system DS. For example, a first transfer unit TU1 may transfer a substrate released/removed from the photolithography processing system PS to the substrate drying system DS. The substrate drying system DS may perform a wetting process and a drying process on a substrate. The substrate drying system DS may include a loading port LP, a transfer zone TZ, a wetting apparatus B, a second transfer unit TU2, a substrate weight measuring apparatus M, a drying apparatus A, a second heating apparatus BC, a cooling apparatus CPC, and a controller C.

The loading port LP may be a port on which a substrate is loaded. For example, the loading port LP may load thereon a substrate that has experienced (e.g., been treated in) various semiconductor fabrication processes. A plurality of loading ports LP may be provided in the substrate drying system DS. A plurality of substrates may be loaded on the plurality of loading ports LP. For example, a corresponding substrate may be loaded on each loading part LP. Unless otherwise especially stated, a single loading port LP will be discussed for ease of description. For example, the single loading port LP may represent each of the loading ports LP.

The transfer zone TZ may be a region where a substrate loaded on the loading port LP is transferred. For example, the second transfer unit TU2 may transfer a substrate loaded on the loading port LP to the wetting apparatus B and/or the drying apparatus A. The transfer zone TZ may cover a plurality of loading ports LP. For example, the transfer zone TZ may be connected to a plurality of loading ports LP such that the second transfer unit TU2 accesses the plurality of loading ports LP.

The wetting apparatus B may be a device in which a wetting process is performed on a substrate. The wetting apparatus B may include a wet chamber WC and a fluid supply FS.

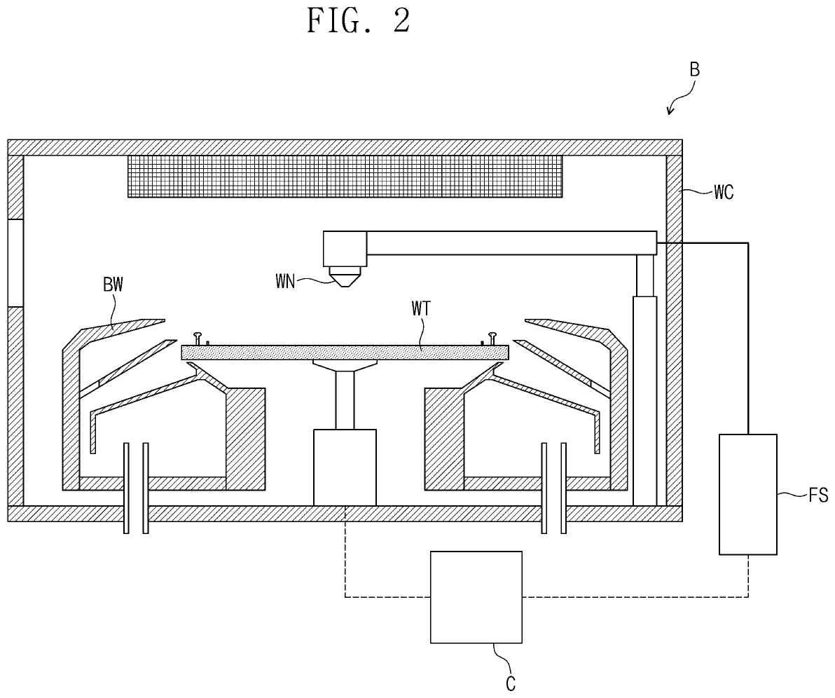

The wet chamber WC may provide a space in which a wetting process is performed. When a substrate is disposed in the wet chamber WC, the substrate may be coated thereon with liquid, such as various chemicals and/or isopropyl alcohol (IPA). The liquid coating may be fulfilled in various ways. For example, a liquid may be sprayed on a substrate that rotates, and a centrifugal force may uniformly distribute the liquid on the substrate. A plurality of wet chambers WC may be provided in the wetting apparatus B. For example, two wet chambers WC may be provided in the wetting apparatus B. The two wet chambers WC may be disposed to face each other. For example, the two wet chambers WC may be disposed side by side. However, a single wet chamber WC will be discussed below for ease of explanation, and the single wet chamber WC may represent each of the wet chambers WC. The wet chamber WC will be further discussed in detail below with reference to FIG. 2.

The fluid supply FS may supply the wet chamber WC with fluid. The fluid supply FS may include a fluid tank and a pump. A process fluid may be defined to indicate a fluid with which the fluid supply FS supplies the wet chamber B. The process fluid may include or be formed of various chemicals and/or water. For example, the process fluid may include or may be a developer or isopropyl alcohol (IPA).

The second transfer unit TU2 may transfer a substrate. For example, the second transfer unit TU2 may transfer a substrate, which is loaded on the loading port LP, through the transfer zone TZ to the wetting apparatus B. For example, the second transfer unit TU2 may transfer a substrate from the loading port LP to the wetting apparatus B through the transfer zone TZ. In addition, the second transfer unit TU2 may unload a substrate from the wetting apparatus B, and may then transfer the unloaded substrate to the drying apparatus A. The second transfer unit TU2 may include an actuator such as a motor. One second transfer unit TU2 may be provided, but the present inventive concepts are not limited thereto.

The substrate weight measuring apparatus M may measure a weight of a substrate. For example, before a substrate passes through the wetting apparatus B and/or the second heating apparatus BC, the substrate weight measuring apparatus M may measure a weight of the substrate. The present inventive concepts, however, are not limited thereto, and the substrate weight measuring apparatus M may measure a weight of a substrate that has passed through the wetting apparatus B. The substrate weight measuring apparatus M may include a measurement chamber 1, an air supply SP, and an air exhaust EP.

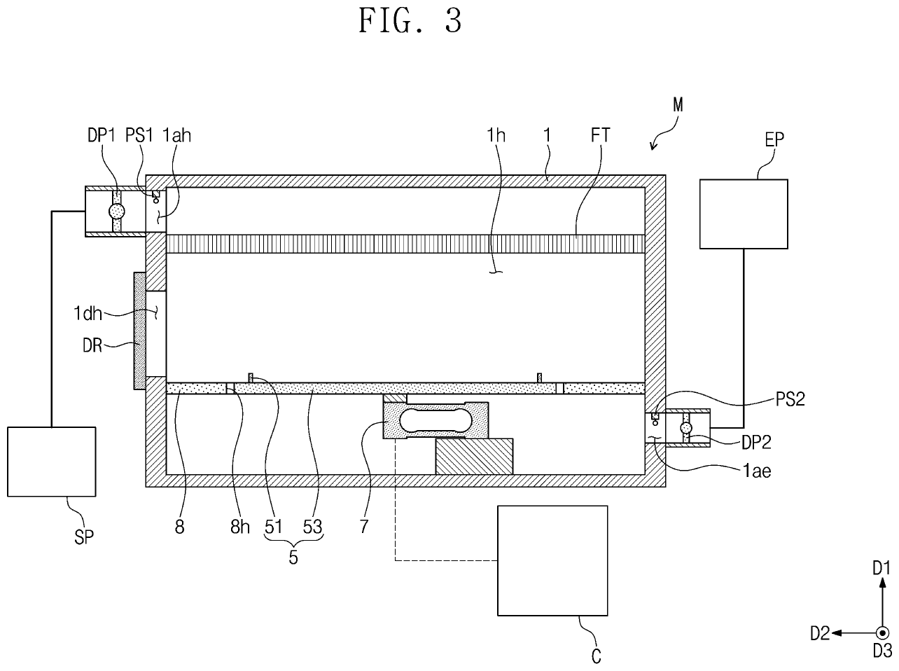

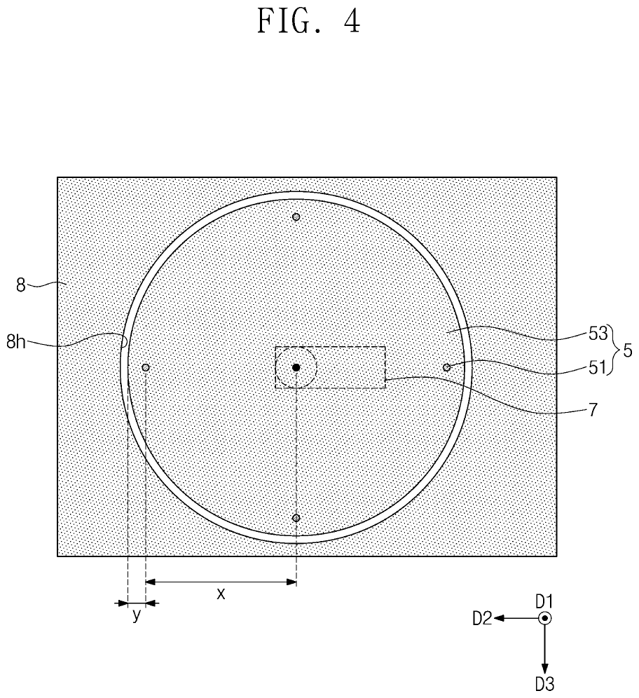

The measurement chamber 1 may provide a space where weight measurement is performed. When the measurement chamber 1 receives therein a substrate, on which the process fluid is coated, released/removed from the wetting apparatus B, a weight of the substrate and a weight of the fluid on the substrate are measured. For example, the weight of the substrate may be measured in an independent space, or in the measurement chamber 1. The measurement chamber 1 may be positioned in the vicinity of the wet chamber WC. For example, the measurement chamber 1 may be positioned immediately next to the wet chamber WC. For example, in one embodiment, there is no other chamber between the measurement chamber 1 and the wet chamber WC. For example, the measurement chamber 1 and the wet chamber WC may share a sidewall placed between the measurement chamber 1 and the wet chamber WC or a sidewall of the measurement chamber 1 may contact a sidewall of the wet chamber WC. The measurement chamber 1 will be further discussed in detail below with reference to FIGS. 3 and 4.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact. Other words used to describe the relationship between elements should be interpreted in a like fashion (e.g., “between” versus “directly between,” “adjacent” versus “directly adjacent,” “combined” versus “directly combined,” etc.).

The air supply SP may supply air. For example, the air supply SP may supply the measurement chamber 1 with air. The air supply SP may control pressure, humidity, and/or temperature of the measurement chamber 1. The air supply SP may include various components capable of supplying air to the measurement chamber 1. For example, the air supply SP may include a temperature humidity air controller (THC). Therefore, the measurement chamber 1 may be supplied with air whose pressure, humidity, and temperature are constant. The present inventive concepts, however, are not limited thereto, and the air supply SP may include a fan and/or a compressor. A detailed description thereof will be further discussed below.

The air exhaust EP may exhaust air from the measurement chamber 1. For example, the air exhaust EP may draw air away from the measurement chamber 1 to allow the measurement chamber 1 to maintain its pressure at a certain/predetermined level. For example, the air exhaust EP may control air pressure in the measurement chamber 1 by controlling air flowing out form the measurement chamber 1. The air exhaust EP may include various components for drawing air. For example, the air exhaust EP may include a pump.

As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”.

The drying apparatus A may be a device to dry a substrate. The drying apparatus A may dry and/or clean a substrate that has passed through the wetting apparatus B and/or the substrate weight measuring apparatus M. For example, the drying apparatus A may remove liquid from a substrate on which the liquid, such as a developer and/or isopropyl alcohol (IPA), is coated in the wetting apparatus B. The drying apparatus A may include a dry chamber 9 and a dry fluid supply 3.

The dry chamber 9 may provide a space in which a drying process is performed. The dry chamber 9 may be positioned in the vicinity of the measurement chamber 1. For example, the dry chamber 9 may be positioned immediately next to the measurement chamber 1. For example, there may be no other chamber between the measurement chamber 1 and the dry chamber 9. For example, the measurement chamber 1 and the dry chamber 9 may share a sidewall placed between the measurement chamber 1 and the dry chamber 9 or a sidewall of the measurement chamber 1 may contact a sidewall of the dry chamber 9. A plurality of dry chambers 9 may be provided in the drying apparatus A. For example, two dry chambers 9 may be provided in the drying apparatus A. The two dry chambers 9 may be disposed to face each other. For example, the two dry chambers 9 may be disposed on opposite sides of the transfer zone TZ. However, a single dry chamber A will be discussed below for ease of explanation. The single day chamber A may represent each of the dry chambers 9.

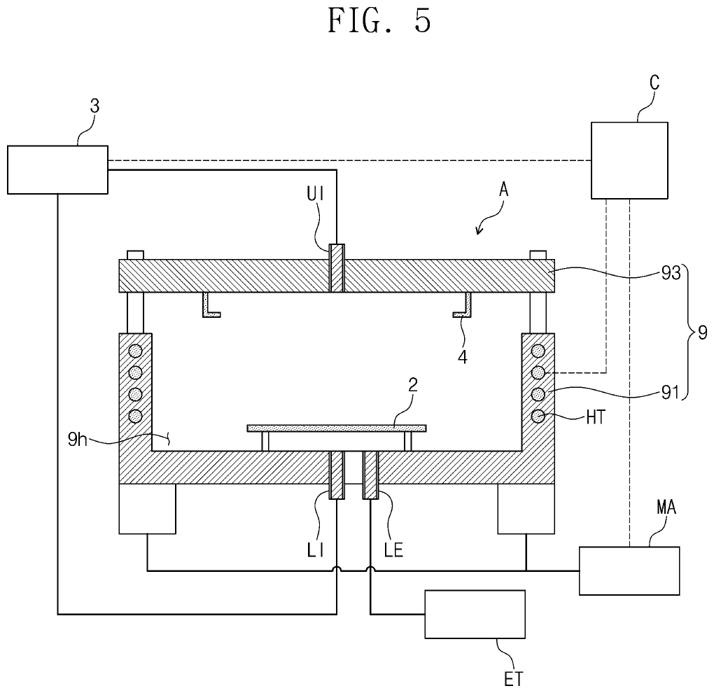

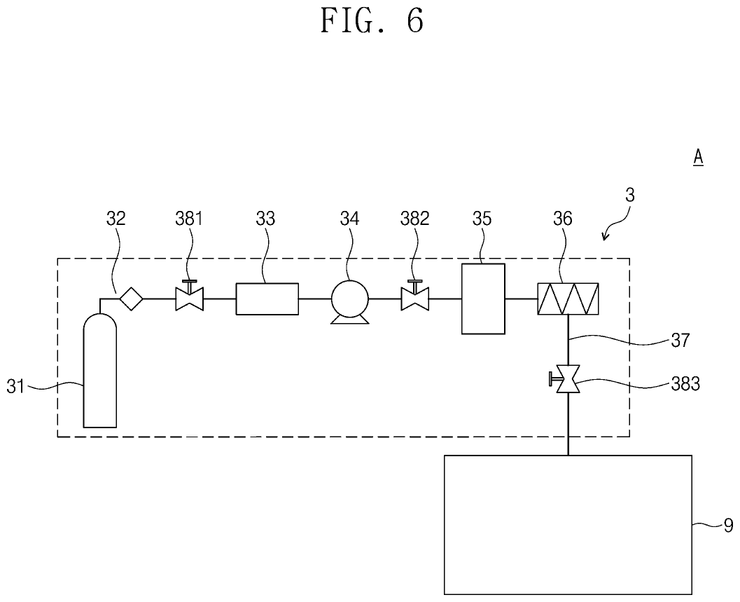

The dry fluid supply 3 may supply the dry chamber 9 with fluid. For example, the dry fluid supply 3 may supply a dry fluid introduced into the dry chamber 9. The dry fluid supplied from the dry fluid supply 3 may be carbon dioxide (CO₂). The carbon dioxide (CO₂) introduced into the dry chamber 9 may be in a supercritical fluid (SCF) state. The drying apparatus A will be further discussed in detail below with reference to FIGS. 5 and 6.

The second heating apparatus BC may heat a substrate. For example, the second heating apparatus BC may remove moisture on a substrate. The second heating apparatus BC may include a chuck and a heater. The second heating apparatus BC may have a structure the same as, substantially the same as or similar to that of the first heating apparatus BCA, but the present inventive concepts are not limited thereto. The second heating apparatus BC will be further discussed in detail below.

Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

The cooling apparatus CPC may cool a substrate. The cooling apparatus CPC may reduce a temperature of a substrate. The cooling apparatus CPC may include a cooling plate provided with a cooling hole.

The controller C may control the wetting apparatus B, the substrate weight measuring apparatus M, and the drying apparatus A. The controller C may control the dry fluid supply 3 to adjust the degree of dryness of a substrate. For example, the controller C may control a flow rate of a dry fluid supplied into the dry chamber 9. A detailed description thereof will be further discussed below.

FIG. 2 illustrates a cross-sectional view showing a wetting apparatus according to some embodiments of the present inventive concepts.

Referring to FIG. 2, the wetting apparatus B may further include a wet stage WT, a wet nozzle WN, and a bowl BW.

The wet stage WT may be positioned in the wet chamber WC. The wet stage WT may support a substrate. For example, a substrate inserted into the wet chamber WC may be disposed on the wet stage WT. The wet stage WT may rotate a substrate. A detailed description thereof will be further discussed below.

The wet nozzle WN may be upwardly spaced apart from the wet stage WT. The wet nozzle WN may be connected to the fluid supply FS. The wet nozzle WN may be supplied with the process fluid from the fluid supply FS, and may spray the process fluid toward the wet stage WT.

Spatially relative terms, such as “beneath,” “below,” “lower,” “above,” “upper,” “upward” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The bowl BW may surround the wet stage WT. The bowl BW may collect the process fluid that is outwardly pushed from the wet stage WT.

FIG. 3 illustrates a cross-sectional view showing a substrate weight measuring apparatus according to some embodiments of the present inventive concepts.

In this description, symbol D1 may indicate a first direction, symbol D2 may indicate a second direction that intersects the first direction D1, and symbol D3 may indicate a third direction that intersects each of the first direction D1 and the second direction D2. The first direction D1 may be a vertical direction. Each of the second and third directions D2 and D3 may be a horizontal direction.

Referring to FIG. 3, the substrate weight measuring apparatus M may include a measurement chamber 1, a measurement door DR, a measurement stage 5, a separation plate 8, a weight detection sensor 7, a filter FT, an inlet damper DP1, an outlet damper DP2, a first differential pressure sensor PS1, and a second differential pressure sensor PS2.

The measurement chamber 1 may provide a measurement space 1h. The measurement chamber 1 may separate the measurement space 1h from an outer space outside the measurement chamber 1. The outer space may be a space outside (e.g., an outside of) the measurement chamber 1. For example, inside of the measurement chamber 1 may be isolated from the outside of the measurement chamber 1, e.g., while a weight of a substrate W is measured. A weight of a substrate may be measured in a state that the substrate is disposed in the measurement space 1h. The measurement chamber 1 may have a hexahedral appearance and/or a cylindrical appearance. The measurement chamber 1 may further provide an insertion hole 1dh, an air inlet 1ah, and an air outlet 1ae.

The insertion hole 1dh may penetrate one side of the measurement chamber 1. The insertion hole 1dh may connect the measurement space 1h to the outer space. A substrate may be introduced through the insertion hole 1dh into the measurement chamber 1. In addition, a substrate may be removed through the insertion hole 1dh from the measurement chamber 1. The insertion hole 1dh may be formed on a lateral surface (e.g., in a sidewall) of the measurement chamber 1, but the present inventive concepts are not limited thereto. The measurement door DR may selectively open or close the insertion hole 1dh.

The air inlet 1ah may penetrate one side of the measurement chamber 1. The air inlet 1ah may connect the measurement space 1h to the outer space. Air in the outer space of the measurement chamber 1 may be introduced through the air inlet 1ah into the measurement space 1h. The air inlet 1ah may be spaced apart from the insertion hole 1dh. For example, the air inlet 1ah may be an aperture separately disposed/distinguished from the insertion hole 1dh. The air inlet 1ah may be formed on a lateral surface (e.g., in a sidewall) of the measurement chamber 1, but the present inventive concepts are not limited thereto. The inlet damper DP1 may selectively open or close the air inlet 1ah. The air inlet 1ah may be connected to the air supply SP. Air supplied from the air supply SP may move through the air inlet 1ah to the measurement space 1h. A detailed description thereof will be further discussed below.

The air outlet 1ae may penetrate one side of the measurement chamber 1. The air outlet 1ae may connect the measurement space 1h to the outer space. Air in the measurement space 1h of the measurement chamber 1 may be discharged through the air outlet 1ae into the outer space (e.g., the air exhaust EP and/or the outside of the measurement chamber 1). The air outlet 1ae may be spaced apart from the insertion hole 1dh and/or the air inlet 1ah. For example, the air outlet 1ae may be an aperture separately disposed/distinguished from the insertion hole 1dh and/or the air inlet 1ah. The air outlet 1ae may be formed on a lateral surface (e.g., in a sidewall) of the measurement chamber 1, but the present inventive concepts are not limited thereto. The outlet damper DP2 may selectively open or close the air outlet 1ae. The air outlet 1ae may be connected to the air exhaust EP. Air in the measurement space 1h may move through the air outlet 1ae to the air exhaust EP. A detailed description thereof will be further discussed below.

The measurement door DR may be combined with the measurement chamber 1 to selectively open or close the insertion hole 1dh. When the measurement door DR closes the insertion hole 1dh, the measurement space 1h may be sealed (e.g., isolated) from the outer space. Thus, when the measurement door DR closes the insertion hole 1dh, a fluid in the outer space may be prevented from being introduced through the insertion hole 1dh into the measurement space 1h. In addition, when the measurement door DR closes the insertion hole 1dh, a fluid in the measurement space 1h may be prevented from being discharged through the insertion hole 1dh into the outer space. The measurement door DR may be automatically opened and closed by a separate drive mechanism (not shown).

The measurement stage 5 may be positioned in the measurement chamber 1. The measurement stage 5 may support a substrate. A weight of a substrate introduced into the measurement space 1h may be measured in a state that the substrate is disposed on the measurement stage 5. The measurement stage 5 may include a pin 51 and a support plate 53.

The pin 51 may extend (e.g., lengthwise) vertically. A substrate may be disposed on the pin 51. For example, the pin 51 may support the substrate. The pin 51 will be discussed in detail below with reference to FIG. 4.

The support plate 53 may support the pin 51. The support plate 53 may have a disk shape in a plan view, but the present inventive concepts are not limited thereto. The weight detection sensor 7 may be positioned below the support plate 53.

The separation plate 8 may surround the measurement stage 5. The separation plate 8 may provide a fluid movement hole 8h. The support plate 53 may be disposed in the fluid movement hole 8h. The separation plate 8 may be outwardly spaced apart from the support plate 53. Therefore, a fluid on the support plate 53 may move through the fluid movement hole 8h to the air outlet 1ae.

The weight detection sensor 7 may detect a weight of a substrate disposed on the measurement stage 5. In some embodiments, the weight detection sensor 7 may be positioned below the measurement stage 5. For example, the weight detection sensor 7 may support the measurement stage 5. The weight detection sensor 7 may be connected to the controller C. The controller C may receive information about a substrate weight detected by the weight detection sensor 7. The weight detection sensor 7 may include various components for detecting a weight. For example, the weight detection sensor 7 may include a load cell. The present inventive concepts, however, are not limited thereto, and the weight detection sensor 7 may include different kinds of sensors.

The filter FT may be positioned below the air inlet 1ah. For example, the filter FT may be positioned between the air inlet 1ah and the measurement stage 5. Air introduced through the air inlet 1ah into the measurement space 1h may be filtered through the filter FT, and then may move onto the measurement stage 5.

The inlet damper DP1 may selectively open or close the air inlet 1ah. The inlet damper DP1 may be directly combined with the measurement chamber 1. Alternatively, the inlet damper DP1 may be connected to an inlet duct (not shown) that extends from the measurement chamber 1. For example, the inlet duct may be interposed between the measurement chamber 1 and the inlet damper DP1.

The outlet damper DP2 may selectively open or close the air outlet 1ae. The outlet damper DP2 may be directly combined with the measurement chamber 1. Alternatively, the outlet damper DP2 may be connected to an outlet duct (not shown) that extends from the measurement chamber 1. For example, the outlet duct may be interposed between the measurement chamber 1 and the outlet damper DP2.

The first differential pressure sensor PS1 and the second differential pressure sensor PS2 may measure a difference in pressure between the air inlet 1ah and the air outlet 1ae. The first differential pressure sensor PS1 may be disposed adjacent to the air inlet 1ah. Alternatively, as shown in FIG. 3, the first differential pressure sensor PS1 may be disposed in the air inlet 1ah. In addition, the second differential pressure sensor PS2 may be disposed adjacent to the air outlet 1ae. Alternatively, as shown in FIG. 3, the second differential pressure sensor PS2 may be disposed in the air outlet 1ae.

The first differential pressure sensor PS1 and the second differential pressure sensor PS2 may collectively constitute a differential pressure gauge. The differential pressure gauge may include various components capable of measuring a pressure. For example, the first differential pressure sensor PS1 may include or may be a manometer and/or a barometer. The second differential pressure sensor PS2 may include or may be a Bourdon tube pressure gauge. The present inventive concepts, however, are not limited thereto, and the differential pressure gauge may include different kinds of pressure gauges capable of measuring a pressure of fluid.

FIG. 4 illustrates a plan view showing a substrate weight measuring apparatus according to some embodiments of the present inventive concepts.

Referring to FIG. 4, a position of the pin 51 may be determined in consideration of size of a substrate. The pin 51 may be disposed to support a substrate. For example, the pin 51 may be spaced apart from a center of the support plate 53, and may be disposed at a first distance x from the center of the support plate 53. The first distance x may be, for example, equal to or greater than about 100 mm. The pin 51 may be spaced apart from a circumference of the support plate 53, and may be disposed at a second distance y from the circumference of the support plate 53. The support plate 53 may have a diameter the same as or similar to that of a substrate. For example, the support plate 53 may have a diameter of about 300 mm. The second distance y may be, for example, equal to or less than about 50 mm. The present inventive concepts, however, are not limited thereto, and the position of the pin 51 may be changed based on a detailed design.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

A plurality of pins 51 may be provided in the measurement stage 5. For example, as shown in FIG. 4, four pins 51 may be provided in the measurement stage 5. The plurality of pins 51 may be disposed to be spaced apart from each other in a horizontal direction. However, unless otherwise especially stated, a single pin 51 will be discussed below for ease of description. The single pin 51 may represent each of the pins 51.

FIG. 5 illustrates a cross-sectional view showing a drying apparatus according to some embodiments of the present inventive concepts.

Referring to FIG. 5, the drying apparatus A may dry a substrate. For example, the drying apparatus A may be configured to remove liquid on a substrate. The drying apparatus A may include a dry chamber 9, a dry heater HT, a dry chuck 4, a blocking plate 2, a chamber drive mechanism MA, and an exhaust tank ET.

The dry chamber 9 may provide a dry space 9h. The dry chamber 9 may include a lower housing 91 and an upper housing 93. The lower housing 91 may be downwardly spaced apart from the upper housing 93. The dry space 9h may be provided between the lower housing 91 and the upper housing 93. The lower housing 91 may be vertically movable. For example, the chamber drive mechanism MA may drive the lower housing 91 to move upwardly to combine the lower housing 91 with the upper housing 93. The lower housing 91 and the upper housing 93 may be combined to separate the dry space 9h from an external environment.

An upper inlet UI may be provided in the upper housing 93. The upper inlet UI may be connected to the dry fluid supply 3. A dry fluid may be supplied from the dry fluid supply 3 through the upper inlet UI to the dry space 9h. A lower inlet LI and a lower exhaust LE may be provided in the lower housing 91. The lower inlet LI may be connected to the dry fluid supply 3. A dry fluid may be supplied from the dry fluid supply 3 through the lower inlet LI to the dry space 9h. The lower outlet LE may be connected to the exhaust tank ET. A dry fluid may be outwardly discharged through the lower exhaust LE.

The dry heater HT may be coupled to the dry chamber 9. The dry heater HT may heat the dry space 9h. For example, the dry heater HT may heat a dry fluid in the dry space 9h. The heating of the dry fluid by the dry heater HT may permit the dry fluid introduced into the dry space 9h to maintain its supercritical state.

The dry chuck 4 may be connected to the upper housing 93. The dry chuck 4 may be downwardly spaced apart from the upper housing 93. For example, the dry chuck 4 may be positioned below the upper housing 93 by a connector connecting the dry chuck 4 to the upper housing 93. A substrate may be disposed on the dry chuck 4. For example, the dry chuck 4 may support a substrate.

The blocking plate 2 may be connected to the lower housing 91, e.g., by a support connecting the blocking plate 2 to the lower housing 91. The blocking plate 2 may be upwardly spaced apart at a certain/predetermined interval from the lower inlet LI and the lower exhaust LE. The blocking plate 2 may block a flow of fluid. For example, the blocking plate 2 may prevent a dry fluid introduced into the lower inlet LI from being directly (e.g., in a straight manner) sprayed to a substrate on the dry chuck 4. For example, the blocking plate 2 may make the dry fluid introduced through the lower inlet LI to have a curved route to contact the substrate disposed on the dry chuck 4 and/or to be dispersed in the dry space 9h first and then to contact the substrate disposed on the dry chuck 4.

The chamber drive mechanism MA may be connected to the lower housing 91. The chamber drive mechanism MA may drive the lower housing 91 to move vertically. The chamber drive mechanism MA may combine the lower housing 91 with the upper housing 93 or may separate the lower housing 91 from the upper housing 93. The chamber drive mechanism MA may include an actuator such as a motor.

The exhaust tank ET may be connected to the lower outlet LE. The exhaust tank ET may receive a fluid that is discharged from the dry chamber 9 through the lower outlet LE.

FIG. 6 illustrates a simplified schematic diagram showing a dry fluid supply according to some embodiments of the present inventive concepts.

Referring to FIG. 6, the dry fluid supply 3 may include a dry fluid source 31, a dry fluid line 37, a supply filter 32, a first valve 381, a condenser 33, a pump 34, a second valve 382, a tank 35, a heater 36, and a third valve 383.

The dry fluid source 31 may supply a dry fluid, e.g., to the dry fluid line 37. For example, the dry fluid source 31 may store and supply a fluid in a gaseous state, and the fluid of the gaseous state will become a supercritical fluid in a later step. When the dry fluid is a CO₂ supercritical fluid, the dry fluid source 31 may store CO₂ in a gaseous state. The gaseous CO2 supplied from the dry fluid source 31 may have a temperature of about 10° C. to about 30° C. In addition, the gaseous CO₂ supplied from the dry fluid source 31 may have a pressure of about 4 MPa to about 6 MPa. The dry fluid supplied from the dry fluid source 31 may move along the dry fluid line 37.

The dry fluid line 37 may provide a pathway along which a dry fluid supplied from the dry fluid source 31 is introduced into the dry chamber 9. The supply filter 32 may be positioned on the dry fluid line 37. The supply filter 32 may filter out foreign substances present in a dry fluid. The first valve 381 may open or close a flow path between the supply filter 32 and the condenser 33, thereby controlling movement of a dry fluid.

The condenser 33 may cool gaseous CO₂ supplied from the dry fluid source 31. Therefore, the gaseous CO₂ may be liquefied in the condenser 33. For example, the CO₂ liquefied in the condenser 33 may have a temperature of about 0° C. to about 6° C. In addition, the CO₂ liquefied in the condenser 33 may have a pressure of about 4 MPa to about 6 MPa.

The pump 34 may increase a pressure of a dry fluid that is liquefied while passing through the condenser 33. For example, the pump 34 may provide a pressure between about 15 MPa and about 25 MPa to the CO₂ liquefied in the condenser 33. In addition, a temperature of CO₂ liquefied in the condenser 33 may become about 15° C. to about 25° C. while the CO₂ passes through the pump 34. The second valve 382 may open or close a pathway between the pump 34 and the tank 35, thereby controlling movement of a dry fluid. The tank 35 may store a dry fluid that is compressed by the pump 34.

The heater 36 may heat a dry fluid that moves along the dry fluid line 37. For example, the heater 36 may heat liquid CO₂ that is compressed by the pump 34. Therefore, the liquid CO₂ may become a supercritical state. The CO₂ that becomes a supercritical state by being heated by the heater 36 may be in a state of high temperature and high pressure. For example, the CO₂ that becomes a supercritical state while passing through the heater 36 may have a temperature of about 60° C. to about 90° C. In addition, the CO₂ that becomes a supercritical state while passing through the heater 36 may have a pressure of about 15 MPa to about 25 MPa. The third valve 383 may control movement of the CO₂ that becomes a supercritical state while passing through the heater 36. The CO₂ in a supercritical state may be introduced into the dry chamber 9 after passing through the third valve 383.

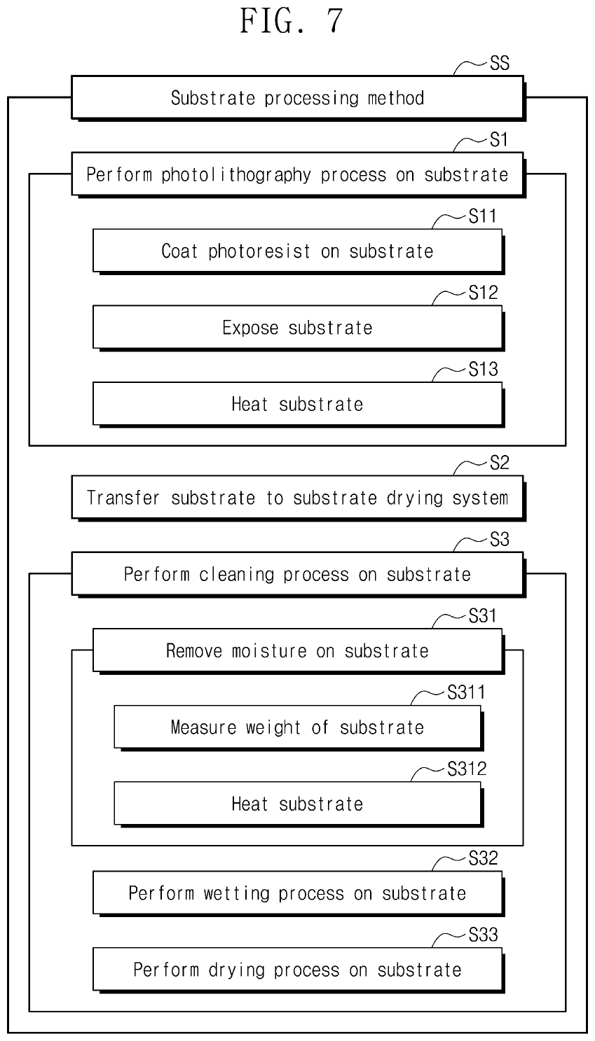

FIG. 7 illustrates a flow chart showing a substrate processing method according to some embodiments of the present inventive concepts.

Referring to FIG. 7, a substrate processing method SS may be provided. The substrate processing method SS may be a way of treating a substrate by using the substrate processing system SPS discussed with reference to FIGS. 1 to 6. The substrate processing method SS may include performing a photolithography process on a substrate (S1), transferring the substrate to a substrate drying system (S2), and performing a cleaning process on the substrate (S3).

The photolithography step S1 may include coating a photoresist on the substrate (S11), exposing the substrate (S12), and heating the substrate (S13).

The cleaning step S3 may include removing moisture on the substrate (S31), performing a wetting process on the substrate (S32), and performing a drying process on the substrate (S33).

The moisture removal step S31 may include measuring a weight of the substrate (S311) and heating the substrate (S312).

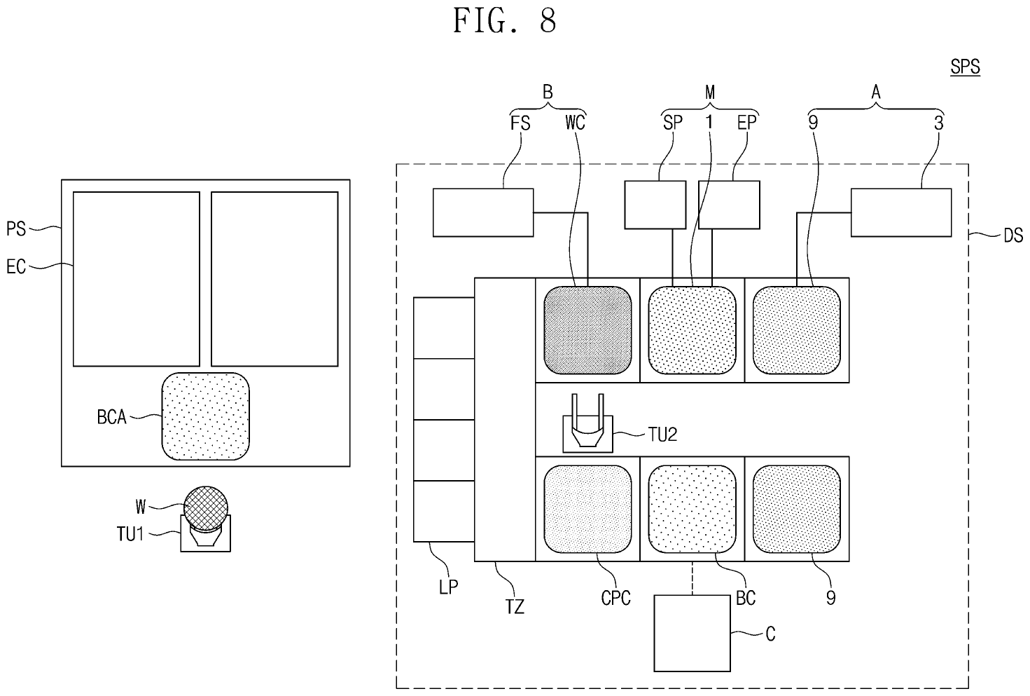

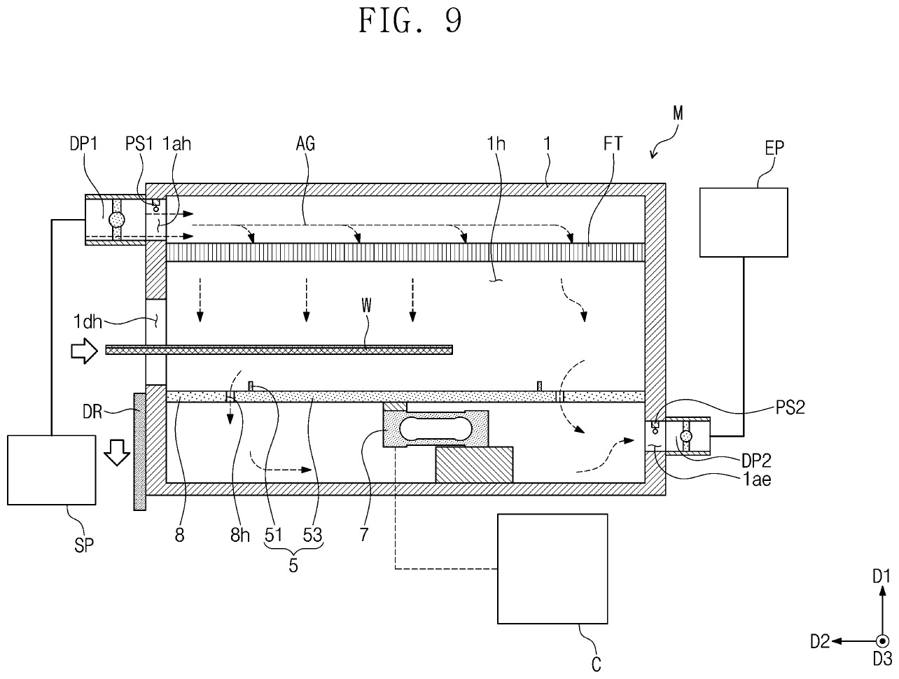

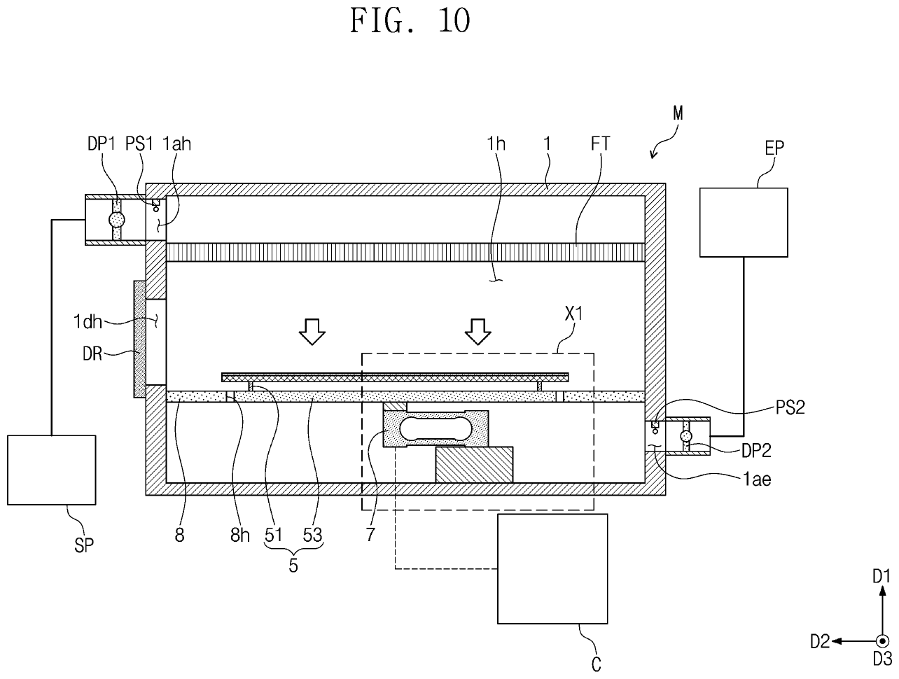

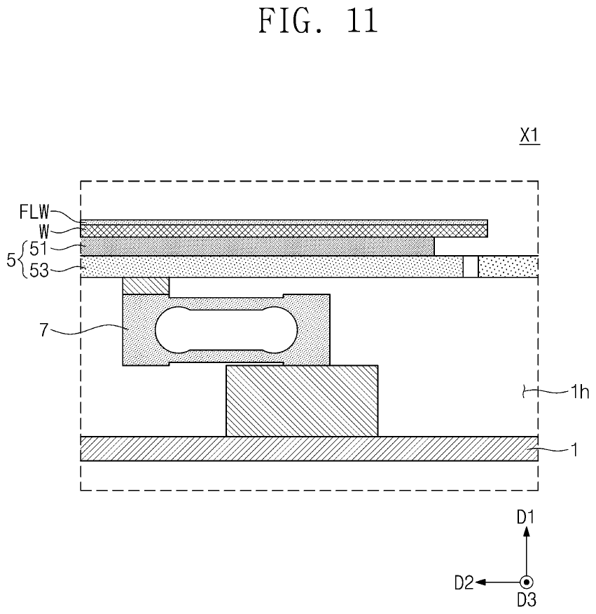

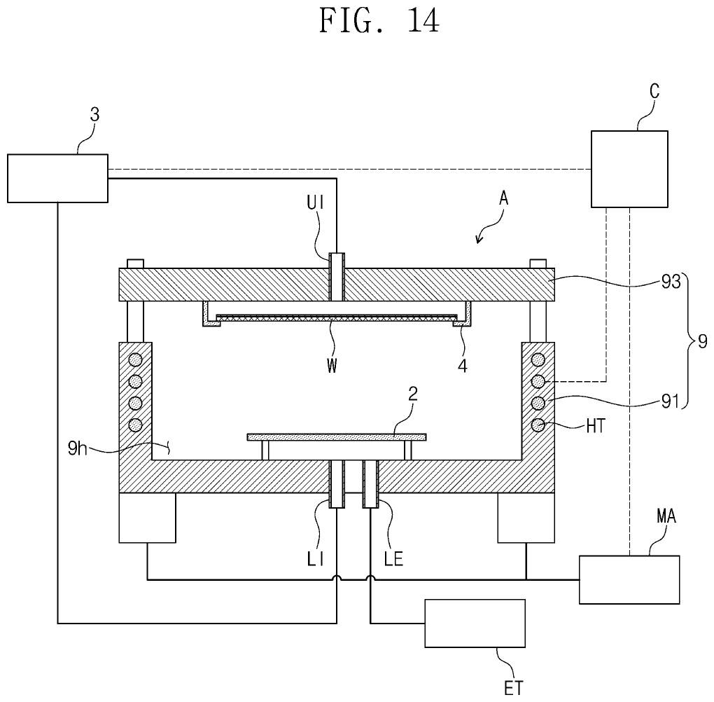

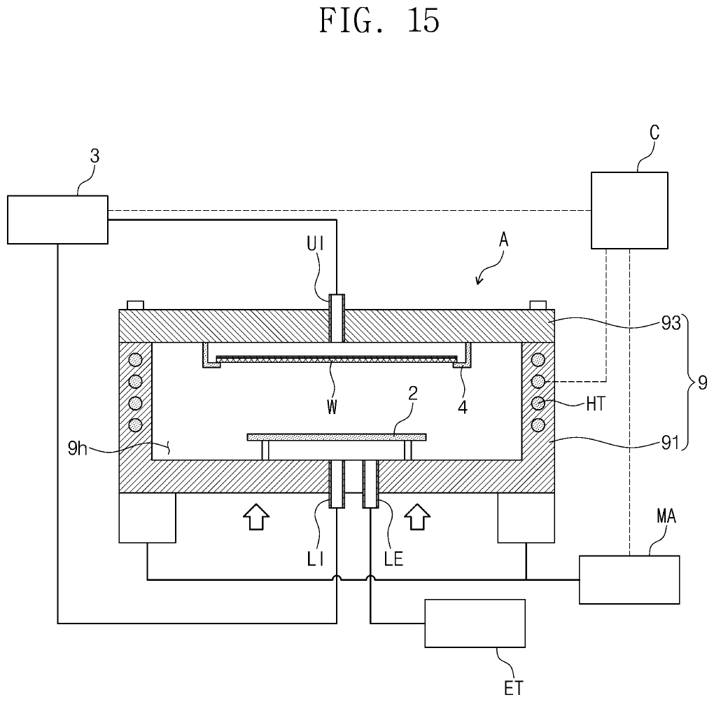

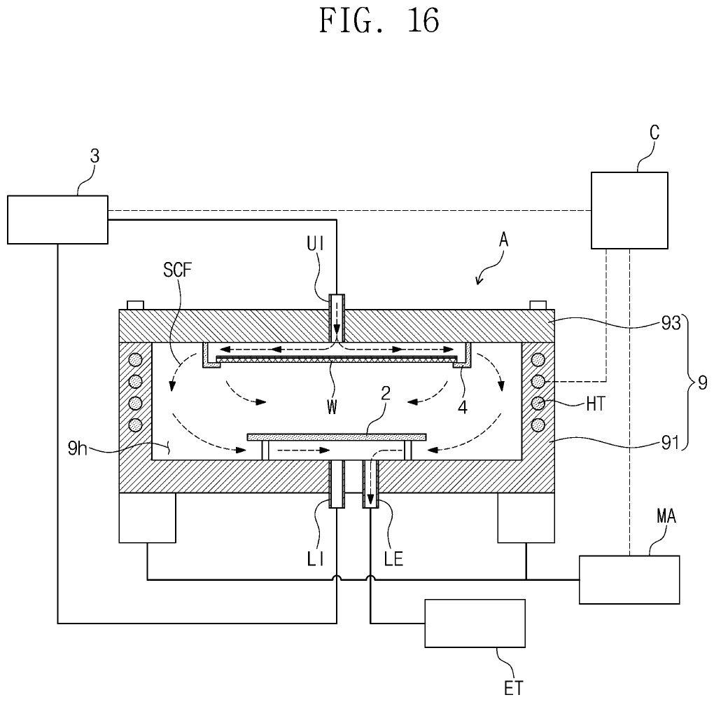

The substrate processing method SS will be discussed in detail below with reference to FIGS. 8 to 16.

FIGS. 8 to 16 illustrate diagrams showing a substrate processing method according to the flow chart of FIG. 7.

Referring to FIG. 7, the photoresist coating step S11 may include coating a photoresist on one surface of the substrate. For example, a spin coating process may be employed to coat the photoresist on the one surface of the substrate.

Referring to FIGS. 7 and 8, the substrate exposure step S12 may include radiating light on a substrate W on which a photoresist is coated. For example, in the exposure apparatus EC, a photomask may be used to perform an extreme ultraviolet radiation on the substrate W. For example, the photoresist coated on the substrate W may be exposed to a patterned extreme ultraviolet radiation formed by the photomask blocking portions of the extreme ultraviolet radiation.

Referring still to FIGS. 7 and 8, the substrate heating step S13 may include allowing the first heating apparatus BCA to heat the substrate W. For example, the substrate W that has passed through the exposure apparatus EC may be heated in the first heating apparatus BCA. The first heating apparatus BCA may perform a bake process on the substrate W that has passed through the exposure apparatus EC. For example, the photoresist coated on the substrate W may form a photoresist layer on the substrate W, and the bake process may be performed to bake the photoresist layer by heating the substrate W and the photoresist layer.

Referring again to FIGS. 7 and 8, the substrate transfer step S2 may include providing the substrate drying system DS with the substrate W including the photoresist layer formed in the photolithography process. For example, the first transfer unit TU1 may transfer the substrate W removed from the photolithography processing system PS to the substrate drying system DS. Before the substrate W reaches the substrate drying system DS, the substrate W may be kept (e.g., may stay) for a certain time at a position outside the substrate drying system DS and outside the photolithography processing system PS. In this procedure, the substrate W may be exposed to atmosphere (e.g., air or gases that exist outside of the chambers). Moisture may be absorbed into and/or adsorbed/attached onto the substrate W exposed to atmosphere. For example, moisture may be present/adsorbed on the substrate W.

Referring to FIGS. 7, 9, 10, and 11, the weight measurement S311 may include placing a substrate in a measurement chamber and measuring a weight of the substrate.

The step of placing the substrate in the measurement chamber may include allowing the second transfer unit TU2 to insert the substrate W into the measurement chamber 1. For example, the second transfer unit TU2 may transfer the substrate W into the measurement chamber 1. For example, the substrate W may be introduced through the insertion hole 1dh into the measurement space 1h. In this stage, moisture FLW may be positioned/adsorbed on the substrate W.

The step of measuring the weight of the substrate may include supplying the measurement space 1h with air AG. For example, before the substrate W is disposed on the measurement stage 5, the air AG may be supplied from the air supply SP through the air inlet 1ah to the measurement space 1h. The inlet damper DP1 may be opened to supply the measurement space 1h with the air AG. The air AG supplied to the measurement space 1h may have a temperature of about 20° C. to about 27° C. The present inventive concepts, however, are not limited thereto, and based on a detailed design, the air AG may be set to have different temperatures.

The step of measuring the weight of the substrate may further include exhausting the air AG from the measurement space 1h. For example, before the substrate W is disposed on the measurement stage 5, the air AG may be exhausted from the measurement space 1h through the air outlet 1ae toward the air exhaust EP. The outlet damper DP2 may be opened to exhaust the air AG.

In measuring the weight of the substrate, the measurement space 1h may maintain a pressure at a certain/predetermined range. The differential pressure gauge may measure the pressure. When the pressure of the measurement space 1h measured by the differential pressure gauge is greater than the certain/predetermined range, the air exhaust EP may discharge the air AG from the measurement space 1h. Alternatively, when the pressure of the measurement space 1h measured by the differential pressure gauge is less than the certain/predetermined range, the air supply SP may supply the air AG to the measurement space 1h.

In such a way, the pressure of the measurement space 1h may be maintained at the certain/predetermined range. In this stage, the pressure of the measurement space 1h may be maintained not higher than that of an outer space. Therefore, a fluid may be prevented from being leaked from the measurement space 1h to an outer space.

The step of measuring the weight of the substrate may further include closing the measurement door DR to seal/isolate the measurement space 1h from an outer space. For example, the measurement door DR may close the insertion hole 1dh to seal/isolate the measurement space 1h.

The step of measuring the weight of the substrate may further include allowing a weight detection sensor to detect the weight of the substrate. The step of allowing the weight detection sensor to detect the weight of the substrate may include allowing the weight detection sensor 7 to detect a weight of the substrate W disposed on the measurement stage 5. For example, the weight detection sensor 7 may detect the weight of the substrate W when the substrate W is placed on the measurement stage 5. The weight detection sensor 7 may detect the weight of substrate W and a weight of the moisture FLW. For example, the weight of substrate W may be measured before the moisture FLW is adsorbed on the substrate W in certain steps, and the weight of substrate W may be measured after the moisture FLW is adsorbed on the substrate W in certain other steps in which case the weight of the substrate W may include the weight of the moisture FLW. The controller C may receive information about the weight detected by the weight detection sensor 7.

The step of measuring the weight of the substrate may be performed twice. For example, the step of measuring the weight of the substrate may include performing a first measurement to measure the weight of the substrate.

The first measurement may be performed in the substrate weight measuring apparatus M. After the first measurement, the substrate W may be transferred to an outside of the substrate weight measuring apparatus M. Afterwards, a second measurement may be performed. The second measurement may be performed in the substrate weight measuring apparatus M. For example, the first measurement and the second measurement may be performed at the same location. The present inventive concepts, however, are not limited thereto, and the first measurement and the second measurement may be performed at different locations. For example, the first measurement may be performed outside the substrate drying system DS. The second measurement may be performed in the substrate weight measuring apparatus M of the substrate drying system DS.

The first measurement and the second measurement may be performed at a time interval. For example, the second measurement may be performed in a predetermined time after the first measurement is performed. Between the first measurement and the second measurement, the substrate W may be kept at a certain/predetermined time on a particular/predetermined position. Alternatively, between the first measurement and the second measurement, the substrate W may be transferred from one place to another place. For example, the first measurement may be performed immediately after the substrate exposure step S12. For example, first measurements and second measurements of weights may be performed with respect to multiple substrates W, and a time interval between a first measurement and a second measurement of a substrate W may be different from time intervals between respective first measurements and second measurements of weights of the other substrates W. In certain embodiments, the time interval between the first measurement and the second measurement of the substrate W may be the same or substantially the same as the time intervals between the respective first and second measurements of weights of the other substrates W.

After the first measurement, the substrate W may be transferred to the substrate drying system DS. While the substrate W is transferred to the substrate drying system DS after the first measurement, the substrate W may be exposed to atmosphere (e.g., the outside of the chambers). For example, before the second measurement and after the first measurement, the substrate W may be exposed to atmosphere. Therefore, moisture in atmosphere may be absorbed into and/or adsorbed onto the substrate W. Thus, the first measurement and the second measurement may yield different results/weights from each other. The result/weight of the second measurement may be greater than the result/weight of the first measurement. A difference in the results/weights between the first measurement and the second measurement may be an amount of moisture absorbed into and/or adsorbed onto the substrate W.

Referring to FIG. 7, the moisture removal step S31 may further include determining a heating condition of the substrate. For example, the weight of the substrate may be used to determine a heating condition of the substrate. The difference in the results/weights between the first measurement and the second measurement may be used to calculate an amount of moisture on the substrate. The calculated amount of moisture may be used to determine the heating condition of the substrate. The heating condition may be a heating time and/or a heating temperature, but the present inventive concepts are not limited thereto.

In some embodiments, it may be possible to collect information about relationship between the heating condition of the substrate and a time during which the substrate is exposed to atmosphere (e.g., a period that the substrate remained outside the chambers). For example, it may be possible to collect data about the amount of moisture on the substrate in accordance with the time during which the substrate is exposed to atmosphere. The heating condition of the substrate may be easily determined by using the data about the amount of moisture on the substrate in accordance/correlation with the time during which the substrate is exposed to atmosphere.

For example, a first condition may be defined to refer to a heating condition of the substrate when the substrate is exposed to atmosphere during a first time. A second condition may be defined to refer to a heating condition of the substrate when the substrate is exposed to atmosphere during a second time. After data is repeatedly collected, it may be possible to determine a heating condition of the substrate without measuring the weight of the substrate. Accordingly, a prompt process may be accomplished.

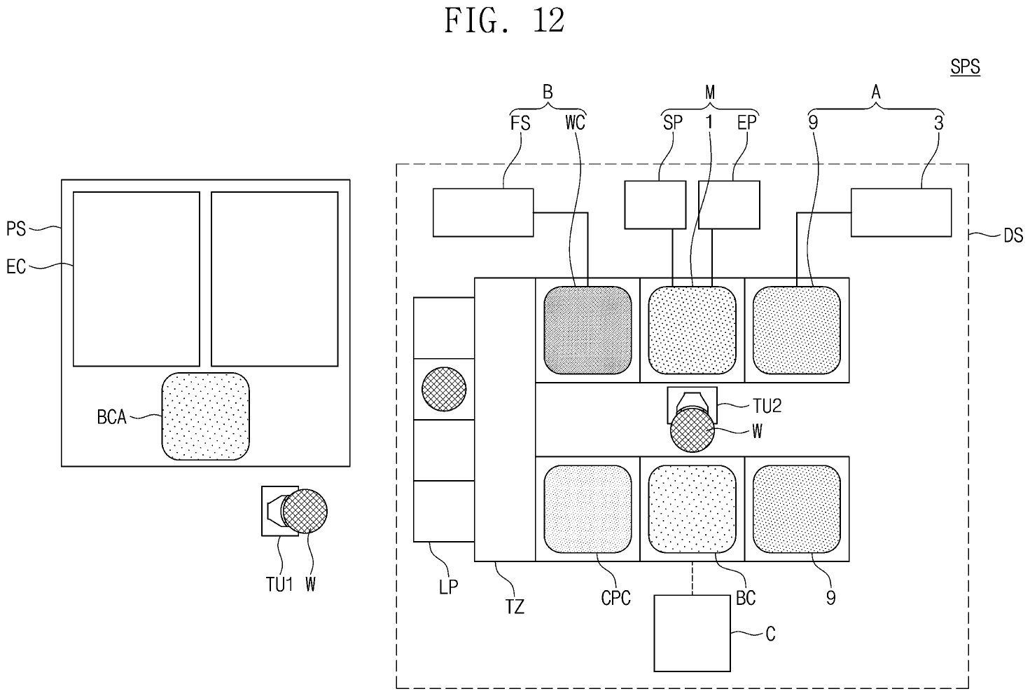

Referring to FIGS. 7 and 12, the heating step S312 may include inserting the substrate W into the second heating apparatus BC. The substrate W may be heated in the second heating apparatus BC. For example, the substrate W may be heated in a heating condition in the second heating apparatus BC. The second heating apparatus BC may use various ways to heat the substrate W. For example, the second heating apparatus BC may heat the substrate W by providing heat to a hot wire disposed below the substrate W. For another example, the second heating apparatus BC may heat the substrate W by radiating light to the substrate W. Therefore, moisture on the substrate W may be eliminated.

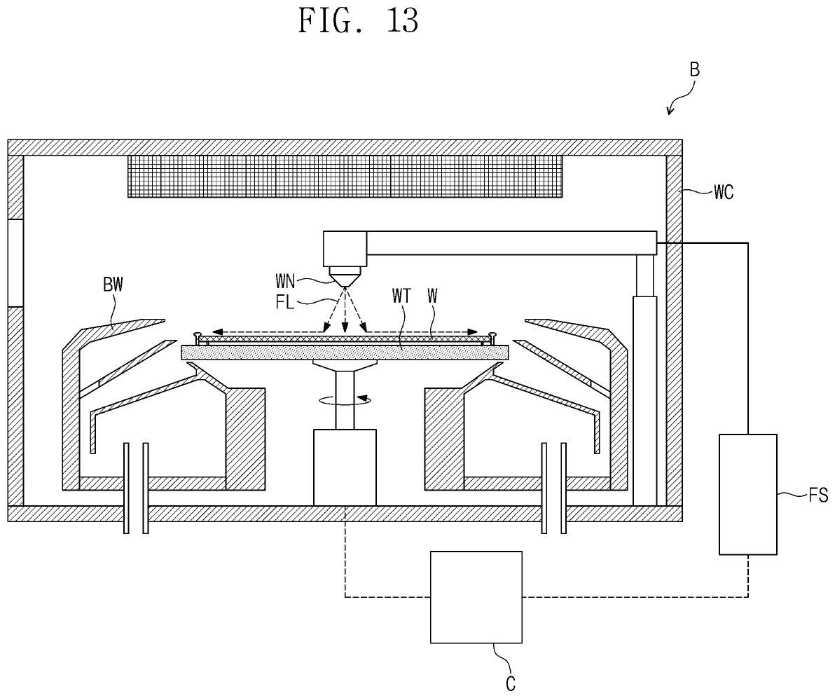

Referring to FIGS. 7 and 13, the substrate wetting step S32 may include placing the substrate W in the wet chamber WC. For example, the substrate W may be disposed on the wet stage WT. In a state that the substrate W is disposed on the wet stage WT, a fluid FL supplied from the fluid supply FS may be sprayed through the wet nozzle WN onto the substrate W. The wet stage WT may rotate the substrate W. When the substrate W is rotated while the fluid FL is sprayed, the fluid FL may be uniformly coated on a top surface of the substrate W. The fluid FL coated on the substrate W may include or may be n-butyl acetate (nBA), but the present inventive concepts are not limited thereto.

Referring to FIGS. 7, 14, 15, and 16, the substrate drying step S33 may include allowing the dry chamber 9 to receive therein the substrate W that has passed through the wetting apparatus B. For example, the substrate W may be transferred to the dry chamber 9 from the wetting apparatus B after the wetting step 32 is performed. The substrate W may be disposed on the dry chuck 4. The substrate drying step S33 may further include sealing the dry chamber 9. In a state that the substrate W is disposed on the dry chuck 4, the lower housing 91 and the upper housing 93 may be combined with each other to seal the dry space 9h. The substrate drying step S33 may further include supplying the dry chamber 9 with a supercritical fluid SCF. The supercritical fluid SCF supplied from the dry fluid supply 3 to the dry space 9h may remove a fluid coated on the top surface of the substrate W. Accordingly, the substrate W may be dried and/or cleaned.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

According to a substrate processing system and a substrate processing method using the same in accordance with some embodiments of the present inventive concepts, before a wetting process and/or a drying process are performed on a substrate, moisture on the substrate may be removed in advance. Thus, in a drying process that uses a supercritical fluid, the moisture may be prevented from remaining on the substrate. The moisture may be difficult to be dissolved in the supercritical fluid. Thus, when the moisture remains on the substrate, the moisture and foreign substances in the moisture may remain on the substrate even after the drying process that uses the supercritical fluid. When the moisture on the substrate is removed in advance, the foreign substances on the substrate may be prevented from remaining on the substrate together with the moisture on the substrate. Accordingly, the substrate may be free of contamination.

According to a substrate processing system and a substrate processing method using the same in accordance with some embodiments of the present inventive concepts, a weight of a substrate may be measured to calculate an amount of moisture on the substrate. Thus, heating may be accurately performed on the substrate. For example, a heating condition of the substrate may be determined to completely remove moisture on the substrate without damaging the substrate. Accordingly, the moisture on the substrate may be removed while reducing/preventing damage to the substrate.

According to a substrate processing system and a substrate processing method of the present inventive concepts, moisture on a substrate may be removed to prevent contamination.

According to a substrate processing system and a substrate processing method of the present inventive concepts, moisture on a substrate may be removed while reducing damage to the substrate.

According to a substrate processing system and a substrate processing method of the present inventive concepts, it may increase a yield of a semiconductor device manufacturing process.

Effects/benefits of the present inventive concepts are not limited to the mentioned above, other effects/benefits which have not been mentioned above will be clearly understood to those skilled in the art from the following description.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. A substrate processing method, comprising:
performing an exposure process on a substrate;
removing moisture on the substrate after the exposure process;
performing a wetting process on the substrate from which the moisture is removed; and
performing a drying process on the substrate after the wetting process,
wherein removing the moisture on the substrate includes:
measuring a weight of the substrate; and
heating the substrate whose weight is measured, and
wherein performing the drying process on the substrate includes:
placing the substrate into a dry chamber; and
supplying the dry chamber with a supercritical fluid to dry a fluid on the substrate.

2. The substrate processing method of claim 1, wherein removing the moisture on the substrate further includes calculating an amount of moisture based on the measured weight of the substrate to determine a heating condition of the substrate.

3. The substrate processing method of claim 2, wherein measuring the weight of the substrate includes:
performing a first measurement to measure the weight of the substrate using a substrate weight measuring apparatus;
transferring the substrate to an outside of the substrate weight measuring apparatus after the first measurement; and
after transferring the substrate to the outside of the substrate weight measuring apparatus, performing a second measurement to measure the weight of the substrate.

4. The substrate processing method of claim 3, wherein determining the heating condition of the substrate includes:
calculating an amount of the moisture on the substrate using a difference in weights between the first measurement and the second measurement; and
determining a heating time or a heating temperature of the substrate based on the calculated amount of the moisture.

5. The substrate processing method of claim 3, wherein
performing the exposure process on the substrate is implemented by an exposure apparatus, and
performing the second measurement to measure the weight of the substrate, performing the wetting process on the substrate, and performing the drying process on the substrate are each implemented by a substrate drying system spaced apart from the exposure apparatus.

6. The substrate processing method of claim 5, wherein the substrate drying system includes the substrate weight measuring apparatus,
wherein performing the first measurement is implemented by the substrate drying system.

7. The substrate processing method of claim 5, wherein the substrate weight measuring apparatus is spaced apart from the substrate drying system.

8. The substrate processing method of claim 1, wherein performing the wetting process on the substrate includes coating n-butyl acetate (nBA) on the substrate.

9. A substrate processing method, comprising:
performing a photolithography process on a substrate;
after the photolithography process, transferring the substrate to a substrate drying system; and
performing a cleaning process on the substrate using the substrate drying system,
wherein the performing of the cleaning process includes:
removing moisture on the substrate after the substrate is transferred to the substrate drying system;
performing a wetting process on the substrate after the moisture is removed; and
performing a drying process on the substrate after the wetting process is completed,
wherein removing the moisture on the substrate includes heating the substrate, and
wherein performing the drying process on the substrate includes supplying the substrate with a supercritical fluid to dry a fluid on the substrate.

10. The substrate processing method of claim 9, wherein performing the photolithography process on the substrate includes:
coating a photoresist on the substrate; and
performing an exposure process on the substrate using an exposure apparatus during coating of the photoresist on the substrate.

11. The substrate processing method of claim 10, wherein performing the photolithography process on the substrate includes heating the substrate after the exposure process is completed.

12. The substrate processing method of claim 9, wherein removing the moisture on the substrate includes:
measuring a weight of the substrate; and
determining a heating condition of the substrate based on the measured weight of the substrate.

13. The substrate processing method of claim 12, wherein measuring the weight of the substrate includes:
performing a first measurement to measure the weight of the substrate; and
performing a second measurement to measure the weight of the substrate,
wherein determining the heating condition of the substrate includes:
calculating an amount of the moisture adsorbed on the substrate using a difference in weights between the first measurement and the second measurement; and
determining a heating time or a heating temperature of the substrate based on the calculated amount of the moisture adsorbed on the substrate.

14. The substrate processing method of claim 13, wherein the second measurement is performed at a location different from a location where the first measurement is performed.

15. The substrate processing method of claim 9, wherein performing the wetting process on the substrate includes coating n-butyl acetate (nBA) on the substrate.

16. A substrate processing system comprising a substrate drying system,
wherein the substrate drying system includes:
a first substrate weight measuring apparatus configured to measure a weight of a substrate;
a heating apparatus configured to heat the substrate removed from the first substrate weight measuring apparatus;
a wetting apparatus configured to spray a fluid on the substrate removed from the heating apparatus; and
a drying apparatus configured to dry the substrate removed from the wetting apparatus,
wherein the first substrate weight measuring apparatus includes:
a measurement chamber that provides a measurement space;
a measurement stage in the measurement chamber; and
a weight detection sensor configured to detect the weight of the substrate disposed on the measurement stage, and
wherein the drying apparatus includes:
a dry chamber; and
a dry fluid supply configured to supply the dry chamber with a supercritical fluid.

17. The substrate processing system of claim 16, further comprising a photolithography processing system spaced apart from the substrate drying system.

18. The substrate processing system of claim 17, wherein the photolithography processing system includes:
an exposure apparatus configured to perform an exposure process on the substrate; and
a second substrate weight measuring apparatus configured to measure the weight of the substrate removed from the exposure apparatus.

19. The substrate processing system of claim 16, wherein the wetting apparatus includes:
a wet chamber; and
a fluid supply configured to supply the wet chamber with a fluid.

20. The substrate processing system of claim 16, wherein the drying apparatus further include a dry chuck in the dry chamber.
